(19) United States
(12) Patent Application Publication
(10) Pub. No.: US 2010/0079322 A1
(43) Pub. Date: Apr. 1, 2010

(54) High noise environment measurement technique

(75) Inventors: Victor Gladshtein, Hashmonaim (IL); Benjamin Maytal, Mevasseret Zion (IL)

Correspondence Address: Telesen Ltd., 24 Amal Street, Afek Park, Rosh Ha'ayin, 48092, IL

(73) Assignee: Telesen Ltd., Rosh Ha'ayin (IL)

(21) Appl. No.: 12/286,487

(22) Filed: Oct. 1, 2008

(51) Int. Cl. H03M 1/06; H03M 1/12

(52) U.S. Cl. 341/142; 341/155

(57) ABSTRACT

An electronic measurement system for extracting a small AC signal from a dominant DC background signal, which can be changing at a rate similar to that at which the desired signal changes. The invention is particularly useful for pulse rate measurement of a subject even while undergoing vigorous motion such as running, by means of pulse oximetry. The measurement technique utilizes a moving window for selecting a part of the input signal, and processing in an A/D converter, an offset part of the signal which falls within a range which covers the window. The method is also more generally employable to any measurement task, where the signal to be extracted is a small AC signal buried within a dominant DC or quasi-DC background, which itself can be changing, and even at a rate similar to that expected of the sought-after AC signal.

### FIELD OF THE INVENTION

The present invention relates to the field of electronic measurements performed in high background noise environments, especially using A/D conversion techniques to counteract the noise environment

### BACKGROUND OF THE INVENTION

There are many measurement environments where the signal to be extracted is significantly smaller than a background signal occurring in a similar frequency range This is particularly true in the field of medical measurements, where some bodily functions being measured may change at a rate commensurate with the subject's pulse rate, while background interference, such as motion artifacts may occur in the same frequency range, but are generally much stronger. Because of the limited range of analog to digital conversion systems, the target signal may be either too small to measure or the system may become saturated because of the large background signal.

One example of such a situation is in the field of pulse-rate measurement itself, which is becoming popular among people active in sports, for determining the efficiency of their exercise. Jogging generally involves a stride rate of the order of 90 steps per minute, which will generally be in the same region as the runner's pulse rate, which could be anywhere from 70 to 140 beats per minute. There are currently available for this purpose, portable devices based on ECG measurements. They usually require wearing a chest strap. There are also wrist-worn watches which require touching the watch with the other hand. Both methods may be inconvenient to use. Electrical methods also require constant electrical contact which may lead to periods of inaccuracy due to loss of contact. Spectroscopic methods (plethysmography, also know as pulse oximetry) offer a contactless system with no chest strap. However, the noise due to motion can be significantly higher than the pulse signal at similar frequencies. While methods for separation exist, the heart rate signal itself may not be observed due to the limited dynamic range of the system analog-to-digital (A/D) converter.

The disclosures of each of the publications mentioned in this section and in other sections of the specification, are hereby incorporated by reference, each in its entirety.

### SUMMARY OF THE INVENTION

The device described in the present disclosure seeks to provide a new electronic measurement system for extracting a small AC signal from a dominant and possibly changing background signal. The device is particularly useful for measurement of the heart rate by means of pulse oximetry, while the subject is undergoing vigorous motion, such as running. Pulse oximetry methods offer the benefit of not requiring a reliable electrical contact with the subject's body, are applied at a single body location and have no requirement for either a chest strap or touching with the second hand. Current optical pulse oximetry systems however, are not generally functional during vigorous movements, such as running, and the devices described in the present disclosure seek to overcome this limitation to a large extent.

Although the exemplary devices and methods are described in terms of such a heart rate measurement system based on pulse oximetry, it is to be understood that the method is generally employable to any measurement task of determining the response to an input impulse, where the signal to be extracted is a small AC signal either buried within a dominant DC background, or with a strong noise signal within the same frequency range as the signal. The invention is thus not intended to be limited by the specific examples used in this application in describing it.

One of the main problems associated with such a measurement situation is that in order to resolve a small sought-after signal buried within a dominant and changing background signal, a measurement system having a very large dynamic range (e.g. 24 bits) is required, since the range of the background system may be as much as two orders of magnitude larger than that of the sought after signal. Expressed in terms of system capabilities, while a typical measurement resolution of the sought-after signal may use a 16-bit ADC and associated digital processing elements, which means that typically 14 bits of useful dynamic range are available for the data handling, the large and dominant background noise signal would generally saturate such a circuit, making measurement impossible with components of such resolution. In order to effectively resolve the sought-after signal buried in the dominant background, much higher resolution than 16 bits would be required.

In order to overcome this problem, and to enable the measurement of small signals within a dominant noisy environment, and without the need to use expensive high resolution digital components, the measurement technique described in the present disclosure utilizes a moving window for selecting a part of the total full-range signal, and for processing in an AND converter only that part of the signal which falls within a limited range which covers the window only. The window is selected by subtracting an offset value from the analog signal to be measured, so that the magnitude of the resulting offset signal is reduced sufficiently that it can be processed by digital components used in the system having a significantly lower resolution. By changing the value of the offset, the window can be moved freely as required to follow the signal being measured. In a practical implementation, the window can be moved either by hardware electronic signals derived by analog processing of the measured signals, or by software commands, based on algorithmic decisions taken on the basis of the measured signals.

Once the signal of interest has been processed within a limited range, techniques can then be applied to the obtained signal output to separate the desired low level signal from the background. Several techniques are known for performing such signal discrimination, one, for instance, relying on the knowledge that the desired signal may have a more regular periodic rate than that of the background signal, which is likely to be more random in nature.

There is thus provided in accordance with one exemplary aspect of the present invention, a method of measuring an analog signal having a predefined dynamic range, comprising the steps of:

(i) providing an analog to digital converter having a measurement range significantly less than that of the predefined dynamic range, and
(ii) subtracting an offset from the analog signal to generate an offset signal, the offset being such that the offset signal falls within the measurement range of the analog to digital converter.

This method can further comprise the step of adjusting the level of the offset if the offset signal moves outside of the measurement range of the analog to digital converter. The step of adjusting the level of the offset may be performed if the offset signal approaches the limit of the measurement range of the analog to digital converter by a predetermined amount. In any of these methods, the predefined dynamic range of the analog signal may be such that it would saturate the analog to digital converter if input thereto directly. In such a case, the method allows the analog signal to be handled by the analog to digital converter without saturation of the analog to digital converter.

In another example of the methods described in this disclosure, there is described a method for measuring response to an input impulse, the method comprising the steps of:

(i) applying the input impulse,
(ii) measuring the response to the input impulse
(iii) converting the response to a digital signal,
(iv) defining a digital sampling window comprising a part of the range of the digital signal, the level of the digital signal within the window being defined as a window digital signal,
(v) determining the level of the window digital signal relative to the window, and
(vi) adjusting the input impulse if the level of the window digital signal approaches an extremity of the window by a predetermined amount, such that the window digital signal remains within the range of the window.

This method may further include the step of defining the difference between the digital signal and the window digital signal as an offset value, wherein the step of determining the level of the window digital signal relative to the window is obtained by subtracting the offset value from the digital signal.

Either of these latter methods enables the response to be ascertained in the presence of a background signal substantially larger than the response.

Also, in these exemplary methods, the input impulse may be adjusted by adjusting the intensity of the applied impulse, and the level of a signal derived from the measured response may then be used to adjust the input impulse. Furthermore, the input impulse may be adjusted by adjusting the energy of the applied impulse, and the time integration of a signal derived from the measured response may then be used to adjust the input impulse. In such a case, the energy of the applied impulse may be adjusted by increasing the length of time of application of the impulse.

According to another implementation of the methods of this application, there is described another method of measuring a response to an input impulse, comprising the steps of:

(i) applying an input impulse,
(ii) measuring the response to the input impulse,
(ii) integrating the measured response over time,
(iv) converting the integrated response to a digital signal at a time determined by a sampling pulse input,
(v) defining a digital sampling window comprising a part of the range of the digital signal, the level of the digital signal within the window being defined as a window digital signal,
(vi) determining the level of the window digital signal relative to the window, and
(vii) adjusting the timing of the sampling pulse input if the level of the window digital signal approaches an extremity of the window by a predetermined amount, such that the window digital signal remains within the range of the window.

In this method, an improvement can be applied by the additional step of subtracting a part of the signal derived from the measured response in order to reduce the effect of a background signal level. In such a situation, the subtraction step may be performed by subtracting the signal derived from the measured response from a reference level. Alternatively, the subtraction step may be performed by differentiating the signal derived from the measured response.

In the method described in the previous paragraph, the window may have a digital range substantially smaller than that of the input digital signal. Additionally, the input impulse may comprise either one of a single pulse or a train of pulses.

Another implementation of the methods of this application involves a method of measuring an analog signal having a predefined dynamic range, comprising the steps of:

(i) providing an analog to digital converter having a measurement range significantly less than that of the predefined dynamic range,
(ii) subtracting an offset from the analog signal to generate an offset signal, the offset being such that the offset signal falls within the measurement range of the analog to digital converter,
(iii) using the analog to digital converter to convert the offset signal to a digital offset signal,
(iv) repeatedly determining the level of the offset digital signal within the measurement range, and
(v) adjusting the offset if the level of the offset digital signal falls outside of a predetermined portion of the measurement range, such that the offset digital signal remains within the measurement range.

In such a case, the offset may be adjusted if the level of the offset digital signal approaches an extremity of the measurement range by a predetermined amount, or even if it extends beyond an extremity of the measurement range. In the latter case, the offset may be adjusted if the offset digital signal is either less than the lower extremity of the measurement range, or more than the upper extremity of the measurement range.

Any of the above-mentioned methods enable an analog to digital converter to handle the analog signal without saturation of the analog to digital converter.

### BRIEF DESCRIPTION OF THE DRAWINGS

The present invention will be understood and appreciated more fully from the following detailed description, taken in conjunction with the drawings in which:

FIG. 1 illustrates schematically a time trace of a signal from a pulse oximetry probe;

FIG. 2 shows a pulse oximetric probe output as a function of time during vigorous motion;

FIG. 3A shows a schematic part of the signal output graph of FIG. 2, showing the total background noise span and a small sampling window used to measure the desired output signal, while FIG. 3B is a schematic illustration of the application of this technique to an exemplary numerical situation;

FIGS. 4A to 4D are circuit block diagrams, illustrating schematically the application of the methods of the present invention to a pulse oximetry measurement system;

FIGS. 5A to 5D show the waveforms obtained at various points in the system, to illustrate the operation of the system;

FIG. 6 illustrates the analog processed signal at the input to the A/D converter of the system of FIGS. 4A-4D;

FIGS. 7A and 7B are schematic flow charts of the algorithms for performing the measurement methods of the present application; FIG. 7A shows a generalized method for making analog signal measurements using digital processing circuits with a smaller dynamic range than that needed to process the anlog signals, while FIG. 7B shows the same methods running on the microprocessor of the exemplary systems of FIGS. 4A-4D;

FIGS. 8A and 8B illustrate examples of oximetry plots against time taken during vigorous motion, without the use of the system described in this disclosure; and

FIGS. 9A and 9B show the same measurements as are illustrated in FIGS. 8A and 8B, but using the system described in this disclosure for performing the measurement, showing how the saturation displayed in FIGS. 8A and 8B has been eliminated.

### DETAILED DESCRIPTION OF EMBODIMENTS

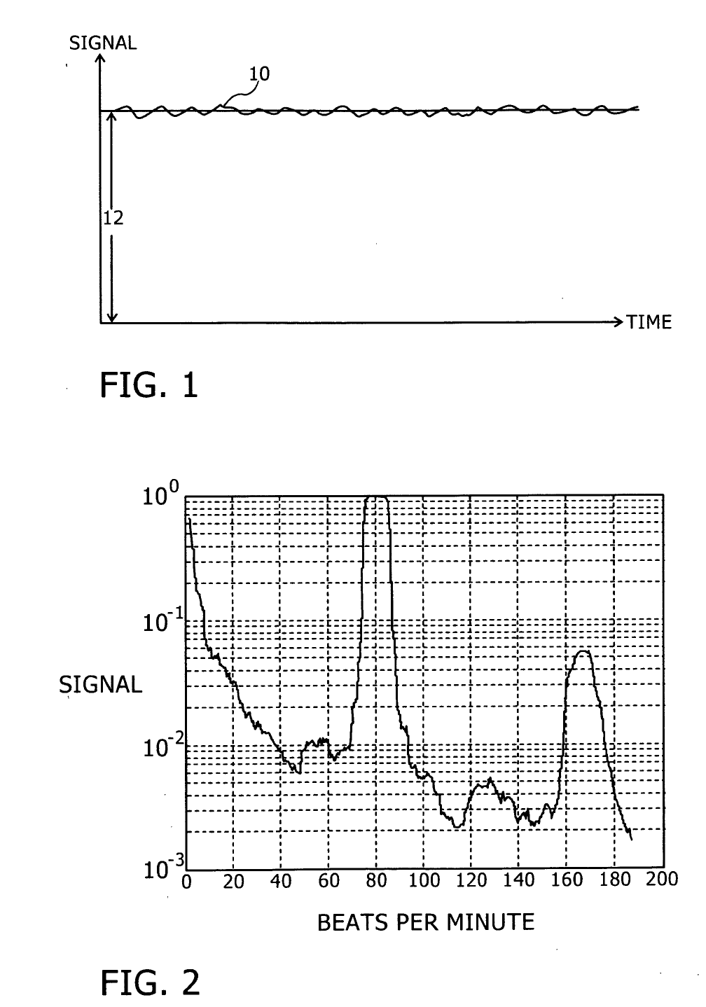

Reference is now made to FIG. 1, which illustrates schematically a time trace of the signal from an exemplary pulse oximetry probe applied to a subject's finger or ear lobe, while the subject is at rest. The oximetry probe is used in this application as an example of a typical system whose output signal of interest is buried within a dominant and changing noise background. The AC component 10 of the signal, which reflects the motion of the blood in the finger, and hence the pulse, is seen to be only a small fraction of the background DC component 12, which is the reflection (or transmission, depending on the optical parameter being measured) of the light from the background body tissue, which does not change with the subject's pulse. In the finger or ear lobe, this ratio is about 1:50 and in the wrist, for instance, about 1:500. This is due to the fact that there are many blood vessels in the finger or ear lobe—which is why they look red—yet comparatively far fewer in the wrist.

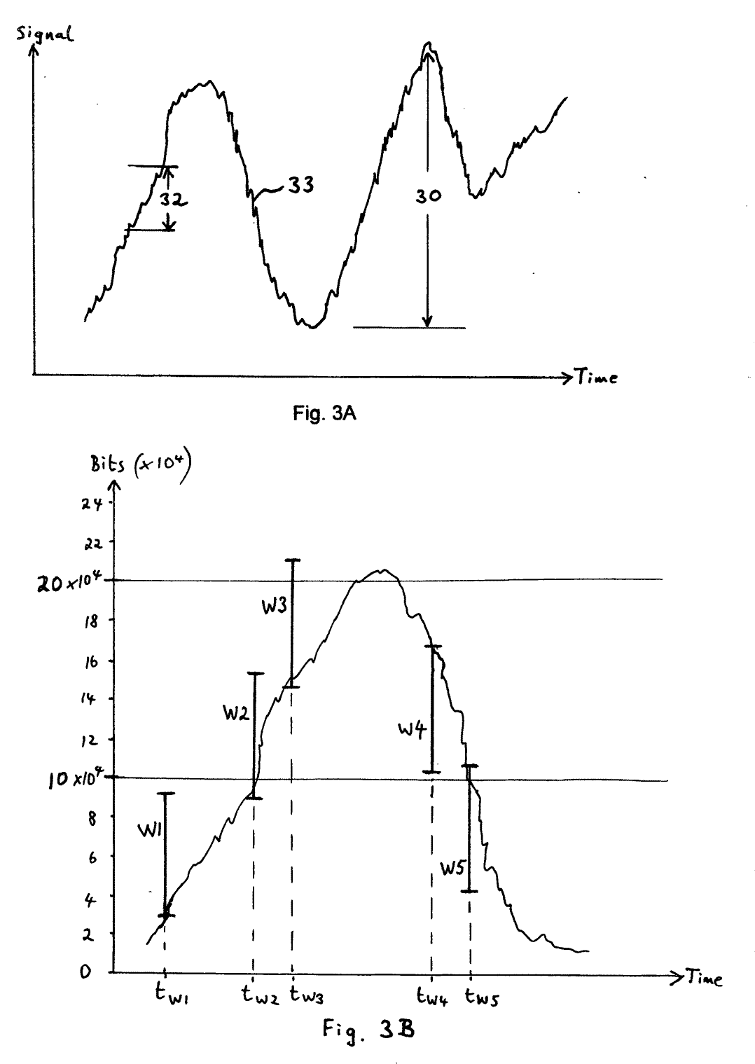

Besides the large static background signal present, motion of the subject can introduce a noise level even larger than this background DC level. This can arise from the strong changes in blood flow which may occur during motion due to the effect of pressure on the blood vessels and to gravitational effects on the blood. Additionally, even simple shift in the position of the light detector on the subject's body part during vigorous motion will generate such a large background signal. Reference is now made to FIG. 2, which shows a frequency domain plot of the signal output of a pulse oximetric probe during vigorous motion. As is observed, the range of signal outputs covers over 2 orders of magnitude, with the strongest signals coming at the frequency range of 70 to 90 beats per minute, and another peak region being in the range 155 to 175 bps. An object of the system of the present application is to extract the desired heart rate signals from an input signal which covers such a large dynamic range.

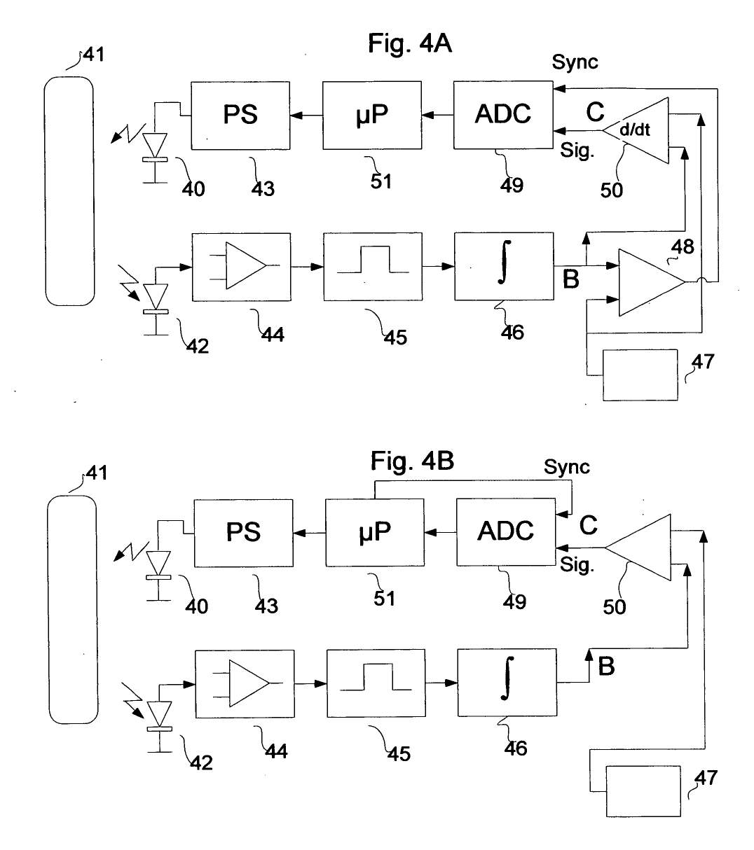

Reference is now made to FIG. 3A, which illustrates an exemplary trace of a section of the pulse oximetric output as a function of time. The small changes 33 are typical of the noise output of the oximetric measurement, while the large amplitude swings 30 may be due to the pulse generated signals which it is desired to measure, onto which is impressed a dominant signal, which is the background motion noise signal, which it is desired to eliminate in the measurement. It is known that the signal from the subject's movement may be of the order of two orders of magnitude larger than the heart rate signal. Some prior art optical heart rate systems use a high pass filter to eliminate the DC signal, and the filtered output is then amplified for display. While this method may be able to handle the static DC background signal, it may be problematic in the presence of motion, since the strong motion signals may saturate the system. One such prior art system has been described as being suitable for pulse measurement during motion, but limits this motion to “rubbing and tapping”. However, such systems may not generally be suitable for use during vigorous movement, such as walking or running.

Referring again to FIG. 3A, a method is illustrated by which the circuitry and algorithms described in the present application are able to handle the problem of a background noise signal of this magnitude. When digital signal processing is used to handle such signals, the range of the desired AC signal itself may require only a 12-bit or a 16-bit A/D converter, but the need to cover the entire span of the measurement, i.e. the absolute value of the measurement including any backgrounds, may require an additional 10 bits or more, and an A/D converter of such precision would be too expensive for use in such an instrument, designed for popular use. The system described in the present application attempts to overcome this problem by utilizing a sampling window 32 of limited dynamic range to measure the desired output signal, and which is designed to follow the amplitude of the total signal. As soon as the sampled part of the signal extends beyond the limited dynamic range of the window, the window is shifted to a new position by the application of a new offset applied to the signal, so as to bring the sampled part of the signal back into the range of the window. Once the window has been shifted to a new offset position, measurement of the signal can continue within the limited dynamic range of the window. The electronic circuitry samples the contents of the window and shifts the window when necessary, at a rate much faster than the rate of change of the signal to be measured. Thus, for a signal which is to be measured having a frequency of the order of 2 Hz, which is typical of a heart rate phenomenon, a much faster sampling and window correction rate is used, typically up to the order of 500 Hz or more. The window can thus move rapidly to keep up with the large swings of the signal due to the background, while the sought after signal is extracted from the signal data within the window, by one of the signal processing methods known in the art for this purpose. Since the window position is adjusted to keep the signal of interest within its limited amplitude range, it can handle the signal of interest at its characteristic rate of change without undue perturbation by the much larger background signal.

In practice, the system is designed to follow the digital signal level within the selected window, and when the bit occupation approaches one end of the window, whether almost filled up with bits towards the top end of the window, indicating a rising signal, or whether an almost empty window with only a few bits, indicating a falling signal, the system acts by adjusting the offset to move the window in the direction in which the signal is moving, whether up or down, in order to define another window of limited range. By this means, an extended dynamic range can be simply obtained without the need to compromise on the use of low-cost A/D converters, and without significant drowning of the signal by strong background quasi-DC signals, which would send the digital detection circuits into saturation.

Three different exemplary methods are now described by which it is possible to carry out this movement of the measurement window:

(i) According to a first method, the window is moved by changing the level of the impulse input for the phenomenon being measured. Thus, in the exemplary case of the pulse oximetry system, if the circuitry detects, for instance, that the signal in the digital window is approaching the lower end of its range, the illumination intensity on the tissue can be increased such that the output from the sensor increases, and the window is thus effectively moved to bring the signal back into range again. The offset used in the previous measurement, this being the difference between the absolute value of the measurement, and the value used within the measurement window, is added to the new value of the window reading in order to give the true output signal. Conversely, if the signal is climbing out of the window range, by reducing the illumination intensity on the tissue, the window is moved to keep the signal within the range of the window. The change in level of illumination is determined by a feedback system which samples the output signal at a high rate, and generates a signal for shifting the window appropriately when the sampled signal approaches the upper or lower end of the window range.

(ii) However, and especially in biological systems, since the output of the phenomenon being measured may not be linear with the impulse input to the system, simple increase of input intensity may not result in a linearly corresponding increase in bodily response. Taking as an example the pulse oximetry measurement system, for a fixed optical pulse input a measurement outputting a low optical signal, indicating a low level of blood flow, may not have the same response sensitivity as a measurement showing a high optical output. Conversely, for a given blood level, the measured output may not be a linear function of the optical input. For this reason, according to a second method for shifting the window position, a fixed intensity source is therefore used, and the level of total illuminating energy input is changed by changing the length of time of the illumination. An integrator may then used to convert the total time-accumulated output into an output voltage. Expressed in terms of energy input and detection, by increasing the time duration of the applied impulse, for a fixed impulse level, the input energy is increased. This energy can then be measured by means of a signal integrator in the detection circuitry to provide the energy output of the bodily response resulting from that impulse input. By this means, the lack of linearity of the bodily response to the light intensity is overcome, since the input intensity is not changed, only its duration. Non linear effects may still be present using this method, but they are less than those arising from changing the intensity of the input impulse illumination.

Furthermore, in order to avoid interference from stray inputs, such as the ambient light in the pulse oximetry example, a train of pulses of fixed width but of variable train length may be used instead of a single pulse of varying width. Phase sensitive detection at the pulse train frequency may then be used to demodulate the output, and thus to eliminate the background interference effect. Alternatively, the pulse widths or the aspect ratio may be varied, with increasing pulse widths or aspect ratio leading to increased energy input to the subject.

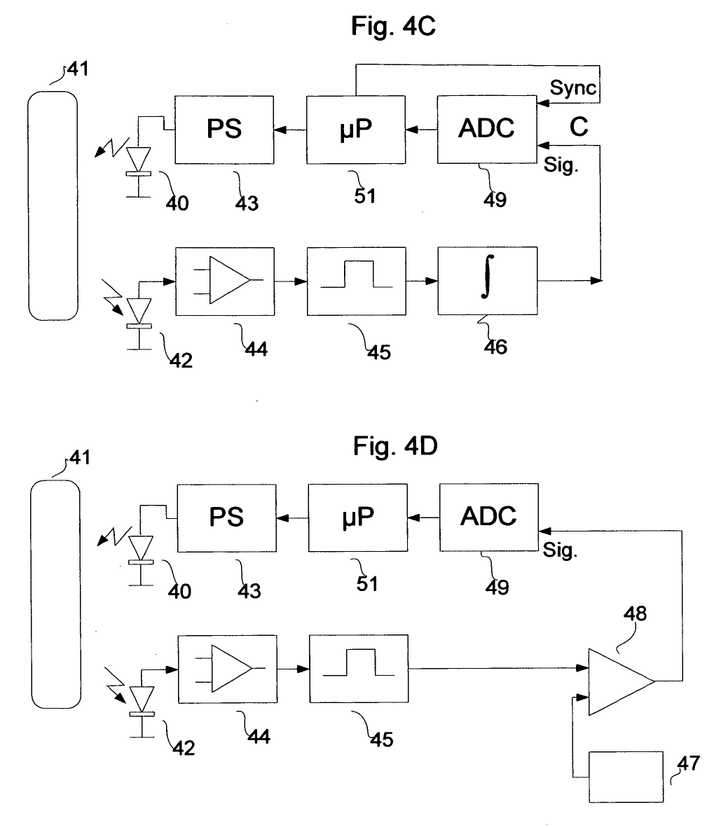

(iii) A third method of moving the window can be performed by changing the sampling time at which the ADC samples the output of the integrator. The ADC converts this integrated analog output to a digital value for input to the microprocessor, at a point in time when a sampling command signal is given to perform the conversion. The later the sampling point in time, the larger will be the equivalent signal input to the signal processing algorithm for shifting the window. Thus, the magnitude of the shift can be controlled by the timing of the ADC sampling point. This method of shifting the window, in contrast to the previous two methods, operates solely within the electronic regime, and does not involve any physiological interaction with the subject. The impulse input to the subject remains constant, and the measurement window is shifted up or down by simply allowing the received signal integration to continue for a longer or a shorter time, and thus to provide an input signal to the ADC of larger or smaller magnitude, depending on the direction in which it is desired to move the window. The manner by which this procedure is executed by the electronic circuitry of the system will be shown hereinbelow, in connection with FIGS. 4A-D and 5A-5D below.

By any of these methods, an extended dynamic range can be simply obtained without the need to compromise on the use of low-cost A/D converters, and without significant drowning of the signal by strong background quasi-DC signals.

Reference is now made to FIG. 3B, which is an exemplary plot of part of the trace of FIG. 3A, showing the way in which movement of the digital window is achieved to follow the movement of the signal amplitude. The dynamic range of the entire trace is from 0 to just over 2×10⁵, i.e. approaching 20 bits. The sampling window used is 6.4×10⁴, i.e. 16 bits. Starting at point tw₁, the window W1 is positioned to contain signal bits having values from 3.0×10⁴ to 9.4×10⁴. The system continually checks the bit count in the digital window, and when it detects, for instance, at time tw₂ that the digital window is close to being filled to capacity, according to the predetermined criterion for what is determined to be “close to being filled to capacity”, the window is shifted in the direction such that the shifted window is ready to be filled anew by the new signal bits according to the trend observed in the previous window W1. In the exemplary case shown in FIG. 3B, when the reading in W1 reaches typically 95% of the capacity of W1, i.e. approximately 9.0×10⁴, the digital window is moved up in the scale of the absolute digital reading of the input signal, such that window W2 now receives digital readings of, for instance, from 9.0×10⁴ to 15.4×10⁴. It thus continues to track the signal received within its limited 6.4×10⁴ bit size. When W2 is almost filled, detected at time tw₃, the window is again moved by the system, to cover digital counts of from 15.0×10⁴ bits to 21.4×10⁴ bits. In this position, since the signal reaches a peak and begins decreasing, the window stays unchanged until position tw₄ is reached, where the algorithm running on the microprocessor detects that the bits of the digital signal are about to empty the window contents, and is operative to move the window W4 in the opposite direction this time, to follow the falling level of the signal. The window W4 in this example is thus shown to have been moved to cover bits of from 10.2×10⁴ to 16.8×10⁴. Window range W4 is maintained until time tw₅, where the algorithm again detects that the window W4 is about to empty, and the sample window again needs to be shifted down to accommodate the decreasing digital count. The system sampling could be designed to behave differently according to the rate of increase or decrease of the digital signal, moving the window more, or at an earlier point in the filling or emptying process, when the rate of change of the signal is larger. This scheme then better anticipates the direction of movement of the signal level.

Reference is now made to FIGS. 4A to 4D, which are circuit block diagrams, illustrating schematically the application of methods of the present system to a pulse oximetry measurement system. The exemplary systems described cover methods (i), (ii) and (iii) of the above alternative methods for shifting the window. FIG. 4A includes all of the circuit functions which may be used in implementing the present invention, whether methods (i), (ii) or (iii), though it is to be understood that not all of the methods need to use all of the functionalities. The illumination source may be a Light Emitting Diode (LED) 40, supplied by drive current from a LED driver power supply 43. The LED directs its output at the body part 41 of the subject whose pulse is being measured. The LED output may have a variable intensity level determined by the system microcontroller, or it may be a train with a variable number of constant intensity pulses as determined by the microcontroller, or a single pulse of length determined by the microcontroller, all according to which method is used for performing the measurement. The reflected or transmitted light, after passage through the blood vessels and tissue of the subject's body part, is detected preferably on a photodetector 42, and amplified by signal amplifier 44. The amplified signal may be demodulated in demodulator 45, if it is made up of a train of pulses, and may then undergo time to voltage demodulation in the integrator 46. The output of the integrator may be compared with a reference voltage 47 in comparator 48, and the resulting signal applied to the SYNC input of an Analog to Digital converter (ADC) 49. The reference voltage 47 can be used to determine the point in time at which the output of the integrator 46 is sampled at the SIGNAL input of the Analog-to-Digital converter 49, this being one of the methods used for shifting the digital window.

An additional system function, relating to the reduction of the large DC component of the signal, is performed by a differentiator 50, which inputs the output of the integrator together with a difference input from the reference voltage 47. The output of this stage is thus only that part of the signal representative of the detected level above the reference voltage. A large DC background voltage can therefore be removed without the use of an active high pass filter. The reference voltage 47 may be set to the estimated level of the DC background at that time, which may be nominally set at 90% of the total signal, since the DC background signal is known to be at least 90% of the total signal, and generally even more. The output of the differentiator 50 is used as the DC-adjusted SIGNAL input of the A/D converter 49.

As previously mentioned, the A/D converter samples the SIGNAL input at a specific sample time, according to the SYNC input. A delayed time means a stronger input signal, due to the fact that the integrator signal ramp increases with time. The output of the A/D converter 49 is input to the system microprocessor 51, which controls the current supplied by the LED driver 43.

The microprocessor or microcontroller 51 may be programmed to deliver pulses to the LED driver 43, generally at a rate of between 10 pulses a second, up to several hundred per second. These are known as the primary pulses. The width of each primary pulse is preferably of the order of some tens of microseconds. The envelope of each primary pulse itself is preferably made up of a train of even shorter pulses, typically at a frequency a few times higher than that characteristic of the primary pulses, and typically in the range of several hundred kHz, to 1 MHz. The frequency of the primary pulses may be selected in order to eliminate low frequency noise, of up to the several kHz range, such as that coming from ambient lighting or from the sun.

In operation, the microprocessor 51 constantly monitors the content of the digital signal content of the sampling window, and if the digital signal approaches the upper or lower end of the window, as indicated by trending towards a full bit count or a zero bit count, according to the above-described method (i), the microprocessor directs the LED driver 43 to increase or to decrease the illumination respectively, in order to move the window in the desired direction. For method (ii) which uses integration to define the response signal level, this is done in practice by increasing or decreasing the length of the primary pulse train of illumination.

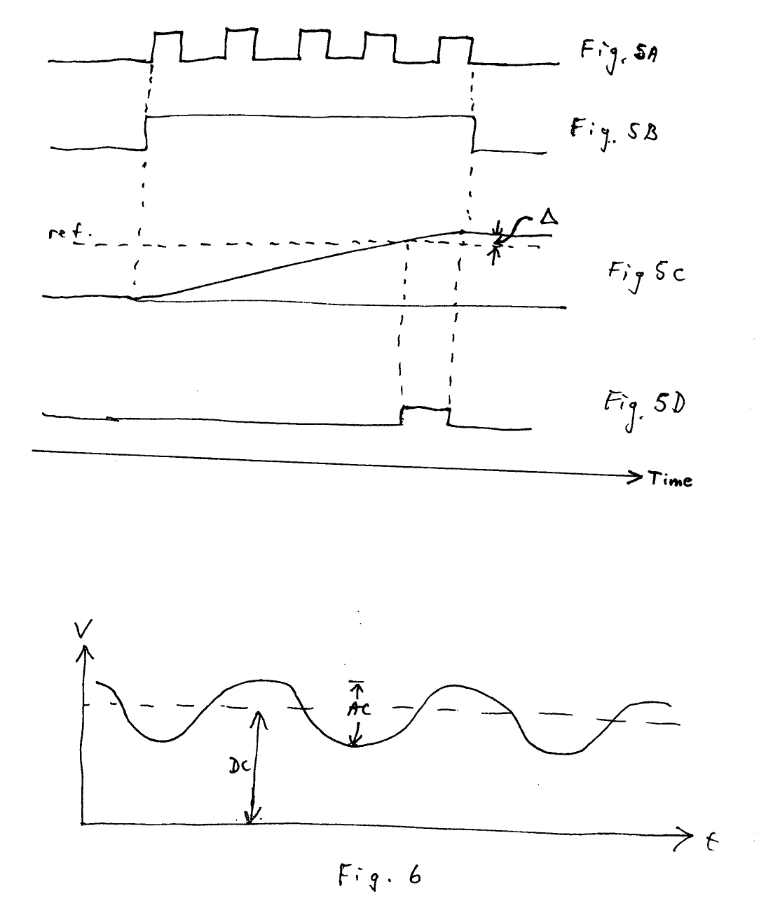

Reference is now made to FIGS. 5A to 5D, which show exemplary waveforms obtained at various points in the system, to illustrate the operation of the system. FIGS. 5A to 5D are illustrative of method (ii) above for controlling the window shift, i.e. by changing the number of pulses applied for each measurement to change the response level of the body. FIG. 5A shows a typical train of illumination pulses emitted by the LED 40. The signal input can be changed by changing the number of pulses or the width of each pulse. This will result in a change in the input energy level. The corresponding detected signal received from the subject's body part is demodulated by the demodulator 45, to provide an envelope of the output primary pulse train signal, as shown in FIG. 5B. This envelope is integrated by the integrator 46 and the output voltage is shown in FIG. 5C. For a given bodily response, i.e. for a constant level response signal, the height of the integrator output signal is proportional to the length of the demodulated signal envelope of FIG. 5B, and will change with the number of pulses and their width.

The level of the reference voltage 47 is also shown in FIG. 5C, marked “ref”, with the level over the reference voltage marked as “Δ”. FIG. 5D shows the signal after reference subtraction and differentiation, which effectively removes the DC component of the signal. This background corrected signal can then be used as the input to the A/D converter 49, whose digital output is processed by the microprocessor 51 in accordance with the particular method used to shift the window, if necessary, and to provide an output reading for the user. The reference voltage thus can play one or both of two roles—it can provide a DC-chopping level to eliminate the large DC or quasi-DC background voltage, and it can provide a SYNC pulse to the A/D converter to instruct it to perform a conversion when the signal detected is over the DC level corresponding to the reference voltage. The selected signal input to the ADC can also be changed by moving the A/D sampling point timing of signal 5C—a later time resulting in a larger value of signal input, as is used by method (iii) for shifting the digital window.

Reference is now made back to FIGS. 4B to 4D which illustrate practically used circuit configurations for different operating methods of the system. In the method used by the circuit of FIG. 4B, the sampling time which the ADC uses to convert the DC-chopped output of the integrator 46, is obtained as a software output from the microprocessor 51. This mode of operation shifts the window by means of electronic adjustment of the sampling time, without adjustment of the illumination, i.e. method (iii) mentioned above. Thus, for instance, if it is detected that, because of a falling response signal, the digital window level is approaching the bottom end of the window range, the algorithm running within the microprocessor 51 may operate to move the sampling time earlier, i.e. to the left in FIG. 5C, such that the signal input to the ADC is reduced, and the digital window is moved downwards to accommodate the bits of the falling response signal within its new range. In this configuration, the reference output 47 is used only in order to adjust the DC chopping level.

FIG. 4C shows an even simpler implementation of the system, in which there is no DC chopping and the integrator output is taken directly to the ADC for conversion at the sampling time determined by the microcontroller 51.

FIG. 4D illustrates schematically the circuit arrangement which may be used for implementing method (i) above. In this implementation, there is no need for an integrator 46, and the demodulated output from 45, the height of which is proportional to the response signal measured from the body, may be compared with the reference 47 if desired, to generate a sampling signal for input to the ADC 49 to provide a digital signal proportional to the signal measured. The decisions about adding or subtracting offset are performed in the microprocessor 51, and the window shift is executed in practice by changing the LED drive input level, as in method (i).

In FIGS. 4B to 4D, although the microprocessor 51 and ADC 49 are shown as separate circuit elements, it is to be understood that they can readily be combined such that the ADC is a functional part of the microcontroller, in which case, the sampling is triggered by an internal command from the software routine.

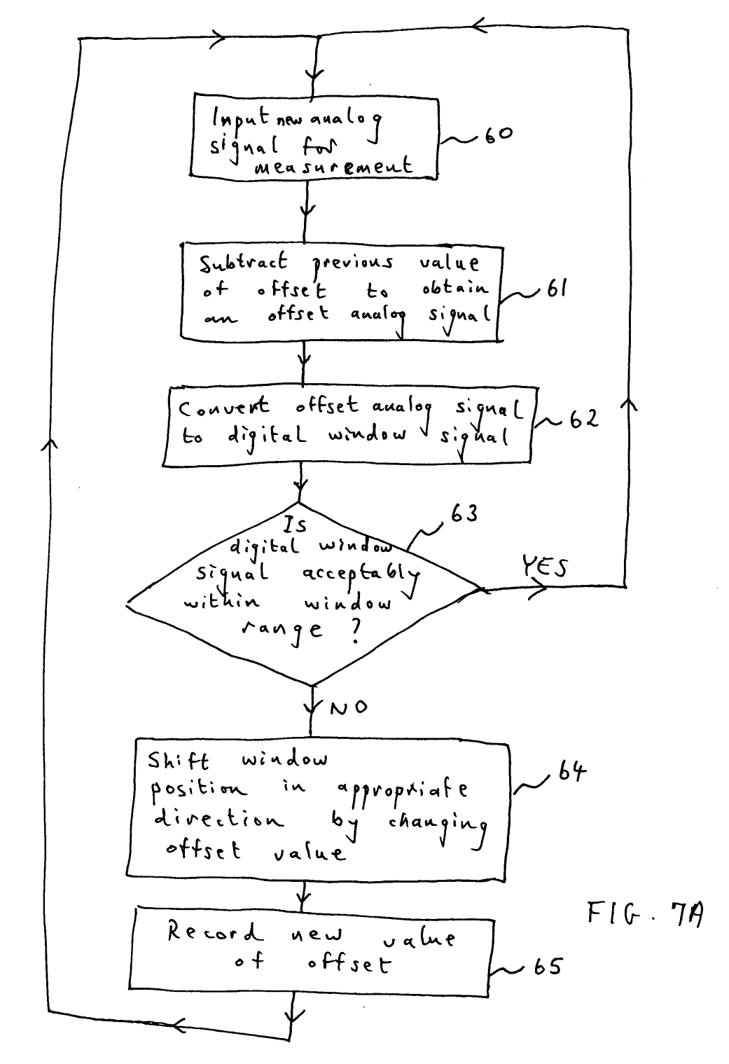

Reference is now made to FIG. 6, which illustrates the analog processed signal at the input to the A/D converter, showing the small AC component representing the measured pulse, without any background component.

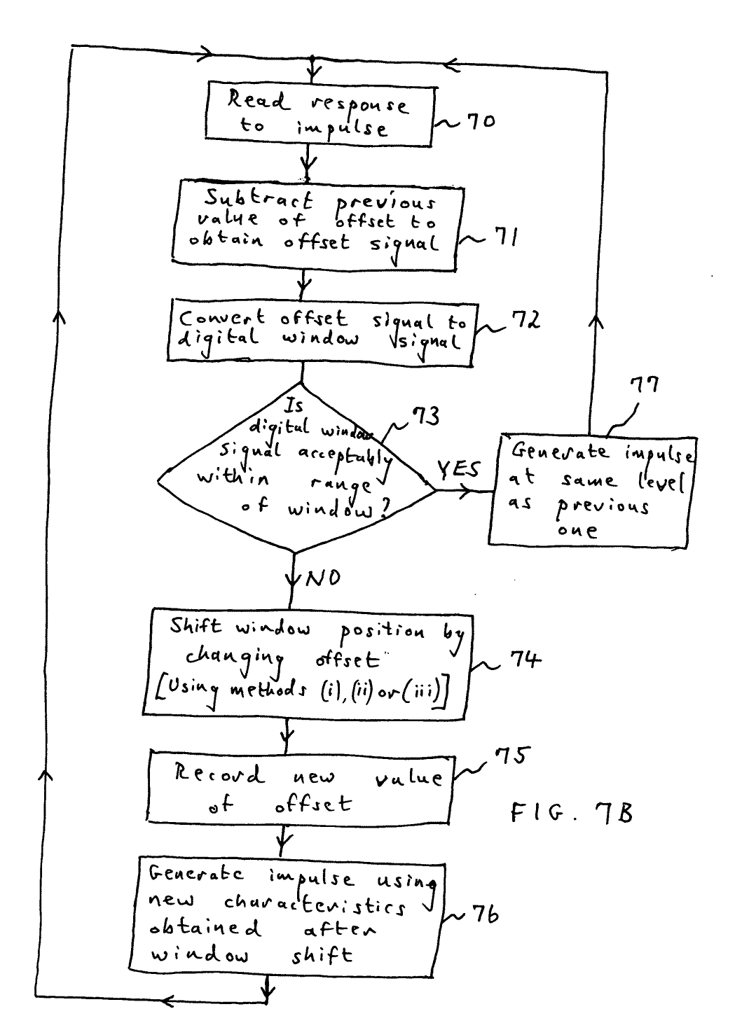

Reference is now made to FIGS. 7A and 7B, which are schematic flow charts of the algorithm running on the microprocessor 51, used to implement the measurement methods described in this disclosure. The algorithms are operative to move the sampling window to follow the level of the signal.

FIG. 7A shows a generic algorithm which illustrates the measurement method without reference to any specific application. In step 60, the analog signal to be measured is input. In step 61, an offset value is subtracted from this analog signal, in order to obtain an offset signal whose magnitude is sufficiently smaller than that of the analog signal that it fits within the window being used to process the signal. This offset value is the difference between the input signal level, and the signal level within the window in which the signal is currently being processed. The offset is that used in the previous measurement step performed on the analog signal. In step 62, the offset signal is converted to a digital signal in an Analog to Digital Converter (ADC) 49, and this digital signal is known as the digital window signal. In step 63, the algorithm determines whether the digital window signal obtained in step 62 is still within the predetermined criteria for inclusion within the range of the currently used window. These predetermined criteria may typically regard a signal close to the limits of the window, even if still within the window, as being “outside” of the window range, so that movement of the window need not be delayed until the signal is already outside of the window. If the signal is still within the predefined “window range”, then there is no need to shift the window position, and the system can continue its measurement procedure using the same offset as the previous measurement, i.e. the same window range. It continues this measurement procedure by taking another input signal reading in step 60, and this entire iterative step is repeated.

On the other hand, if in step 63, it is established that the digital output is close to the edge of the window range, as determined by the predetermined criterion, such as the degree of closeness to the window limit, or if it is even already outside of the window range, the algorithm now operates in step 64 to change the offset value, and hence, the position of the window, to keep the digital window signal within the window range. The offset value is either increased or decreased, depending on whether the digital window signal is at the top or the bottom end respectively of the window range. (Benny, Please check that I got the directions correct). The actual decisions as to when to change the offset are based on the type of decisions illustrated in the exemplary graph of FIG. 3B, and as explained in the associated description thereof. In step 65, following the shift in the window position, the new offset value is recorded, as it must be algebraically subtracted in step 61 of the next iterative measurement, from the actually input signal to transform to the new offset analog signal. Once the new offset value has been stored, the measurement procedure continues by taking another input signal reading in step 60, and this entire iterative step is repeated.

FIG. 7B illustrates an application of the generic method shown in FIG. 7A to the example of a measurement system using an impulse applied to a body, and measuring the response of that body to the impulse. One example of such an application could be the pulse oximetry application described hereinabove. In step 70, the analog response signal to an impulse applied to the body is determined. In step 71, an offset value is subtracted from this analog response signal, in order to obtain an offset signal whose magnitude is sufficiently smaller than that of the analog signal that it fits within the window being used to process the signal. This offset value is the difference between the absolute signal level, and the signal level within the window in which the signal is currently being processed. The offset is that used in the previous measurement step performed on the analog signal. In step 72, the offset signal is converted to a digital signal in an Analog to Digital Converter (ADC), and this digital signal is known as the digital window signal. In step 73, the algorithm determines whether the digital window signal obtained in step 72 is still within the predetermined criteria for inclusion within the range of the currently used window. These predetermined criteria may typically regard a signal close to the limits of the window, even if still within the window, as being “outside” of the window range, so that movement of the window need not be delayed until the signal is already outside of the window. If the signal is still within the predefined “window range”, then there is no need to shift the window position, and the system can continue its measurement procedure using the same offset as the previous measurement, i.e. the same window range. It continues this measurement procedure in step 77, by commanding, in the example of the pulse oximetric measurement, the LED driver 43 to issue a new pulse or a new pulse train impulse, having the same characteristics as the previous one. The resulting bodily response to this impulse is obtained in step 70 again, and this iterative step is repeated.

On the other hand, if in step 73, it is established that the digital output is close to the edge of the window range, as determined by the predetermined criterion, such as the degree of closeness to the window limit, or if it is even already outside of the window range, the algorithm now operates to change the offset value, and hence, the position of the window, to keep the digital window signal within the window range. This can be performed by one of the three methods described hereinabove, namely either (i) by changing the pulse intensity, or (ii) by changing the pulse train length such that the input energy is changed, without necessarily changing the pulse intensity, both of which are executed by instructions given to the LED driver 43, or (iii) by changing the point in time of the sampling after signal integration, which is executed by adjustment of the reference voltage source 47 in FIG. 4A, or by a simple software decision generated by the program running within the microprocessor 51. These alternatives are described generically in step 74 as the process of changing the offset setting, and this change is performed to bring the signal within the acceptable range of the window setting. The actual decisions as to when to change the offset are based on the type of decisions illustrated in the exemplary graph of FIG. 3B, and as explained in the associated description thereof. In step 75, following the shift in the window position, the offset value representing the new impulse and measurement conditions is recorded, as it must be algebraically subtracted from the actually recorded response signal to transform to the window referenced offset signal. In step 76, a new impulse is generated by commanding the LED driver 43 to issue a new pulse or a new pulse train impulse, using the new impulse characteristics obtained after the window shift (according to methods (i) and (ii) only). The resulting bodily response to this new impulse is obtained in step 70 again, and the whole measurement and processing cycle repeats itself as an iterative procedure to ensure that the signal remains within the limited range of the sampling window.

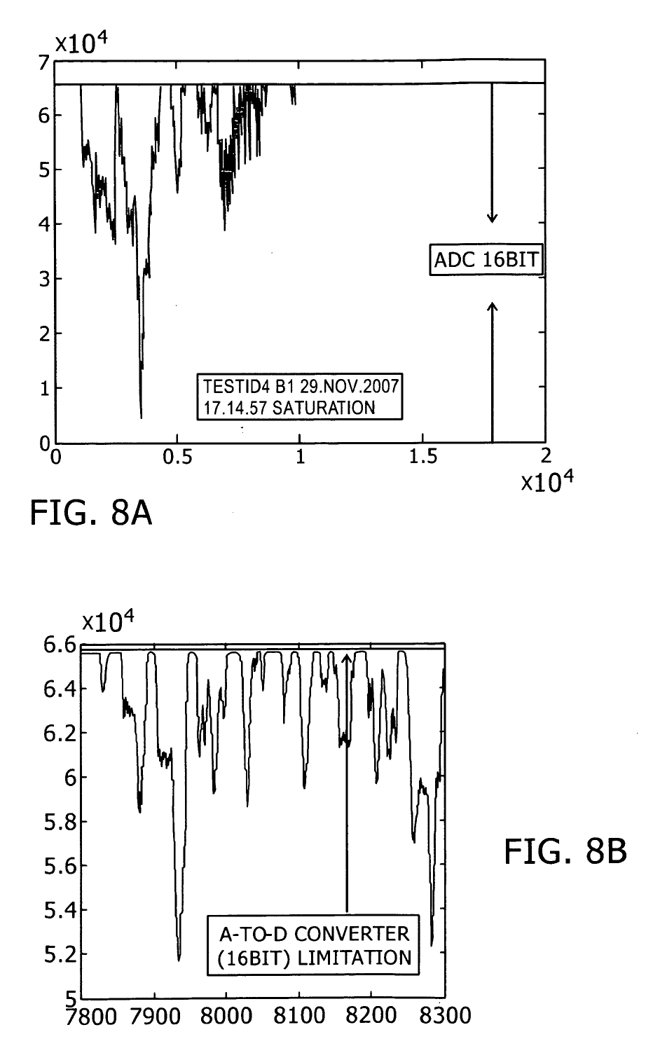

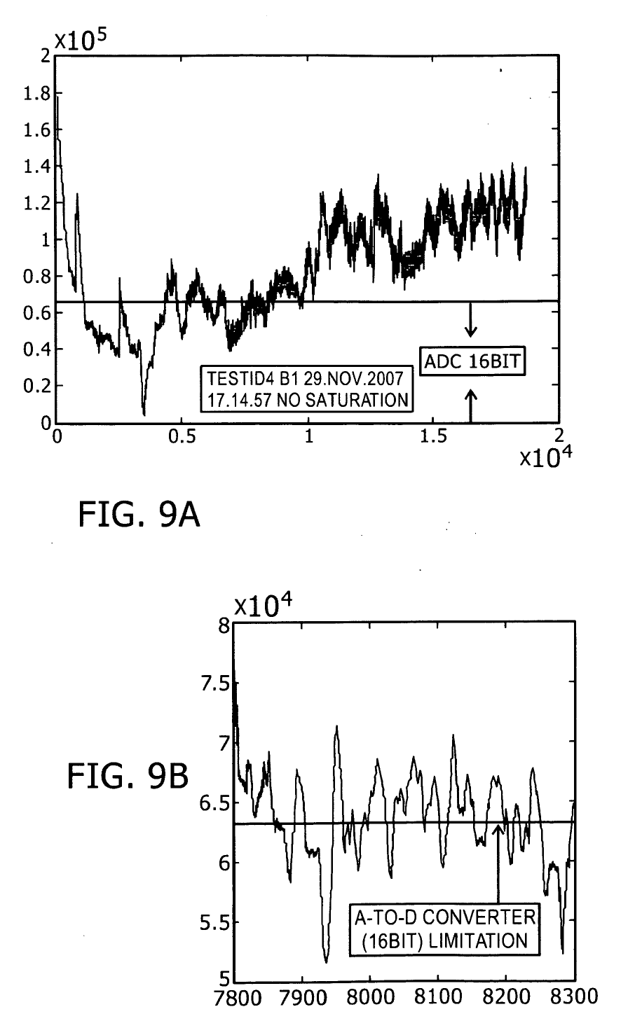

Reference is now made to FIGS. 8A, 8B, and 9A. 9B which illustrate examples of oximetry plots against time taken during vigorous motion, with and without the use of the system described in this disclosure. In these plots, the abscissa is the elapsed time in seconds, while the ordinate is the digital signal output in bits, obtained after analog to digital conversion of the pulse oximetry signal output. In all of the plots, a 16 bit ADC is used, resulting in a dynamic measurement range of 64,000 bits. FIGS. 8A and 8B show how in the plot taken during vigorous motion such as walking or running, the signal enters saturation mode once it gets to the 64,000 bit level, indicated by the horizontal bold line at 6.4×10⁴ bits, and the output digital signal is thus truncated, and of limited dynamic range. FIG. 8A shows the entire signal range from zero up to the saturation level of the 16-bit ADC, while FIG. 8B shows an expanded portion of the output signal, over a magnified 50 msec. section of the time scale of FIG. 8A, from 0.78 sec. to 0.83 sec.

FIGS. 9A and 9B show the same signal obtained by use of the system described in the present application. FIG. 9A shows the full range of the signal obtained using the moving sampling window of the present application, with the 6.4×10⁴ bit limit shown as a horizontal bold line, while FIG. 9B shows an expanded portion of the output signal, over a 50 msec. magnified section of the time scale of FIG. 9A, from 0.78 sec. to 0.83 sec. Even though the same 16-bit ADC is used, the use of the dynamic window technique described in this application, enables a dynamic range of almost 2×10⁵ to be achieved, which is more than three times that obtainable without the present system. However, more important is that this use of this increased dynamic range avoids the signal saturation otherwise encountered, as shown in FIGS. 8A, 8B. Furthermore, this outcome is achieved without the need to use a more costly, higher bit count, ADC than in the prior art systems.

It is appreciated by persons skilled in the art that the present invention is not limited by what has been particularly shown and described hereinabove. Rather the scope of the present invention includes both combinations and subcombinations of various features described hereinabove as well as variations and modifications thereto which would occur to a person of skill in the art upon reading the above description and which are not in the prior art.

1. A method of measuring an analog signal having a predefined dynamic range, comprising the steps of:
providing an analog to digital converter having a measurement range significantly less than that of said predefined dynamic range; and
subtracting an offset from said analog signal to generate an offset signal, said offset being such that said offset signal falls within said measurement range of said analog to digital converter.

2. A method according to claim 1, further comprising the step of adjusting the level of said offset if said offset signal moves outside of said measurement range of said analog to digital converter.

3. A method according to claim 1, further comprising the step of adjusting the level of said offset if said offset signal approaches the limit of said measurement range of said analog to digital converter by a predetermined amount.

4. A method according to claim 1, and wherein said predefined dynamic range of said analog signal is such that it would saturate said analog to digital converter if input thereto directly.

5. A method according to claim 4, and wherein said analog signal is handled by said analog to digital converter without saturation of said analog to digital converter.

6. A method of measuring response to an input impulse, said method comprising the steps of:
applying said input impulse;
measuring said response to said input impulse
converting said response to a digital signal;
defining a digital sampling window comprising a part of the range of said digital signal, the level of said digital signal within said window being defined as a window digital signal;
determining the level of said window digital signal relative to said window; and
adjusting said input impulse if said level of said window digital signal approaches an extremity of said window by a predetermined amount, such that said window digital signal remains within the range of said window.

7. A method according to claim 6, further including the step of defining the difference between the digital signal and the window digital signal as an offset value, wherein said step of determining the level of said window digital signal relative to said window is obtained by subtracting said offset value from said digital signal.

8. A method according to claim 6, wherein said response can be ascertained in the presence of a background signal substantially larger than said response.

9. A method according to claim 6 and wherein said input impulse is adjusted by adjusting the intensity of said applied impulse, and wherein the level of a signal derived from said measured response is used to adjust said input impulse.

10. A method according to claim 6 and wherein said input impulse is adjusted by adjusting the energy of said applied impulse, and wherein the time integration of a signal derived from said measured response is used to adjust said input impulse.

11. A method according to claim 10 and wherein said energy of said applied impulse is adjusted by increasing the length of time of application of said impulse.

12. A method of measuring a response to an input impulse, comprising the steps of:
applying an input impulse;
measuring said response to said input impulse;
integrating said measured response over time;
converting said integrated response to a digital signal at a time determined by a sampling pulse input;
defining a digital sampling window comprising a part of the range of said digital signal, the level of said digital signal within said window being defined as a window digital signal;
determining the level of said window digital signal relative to said window; and
adjusting the timing of said sampling pulse input if said level of said window digital signal approaches an extremity of said window by a predetermined amount, such that said window digital signal remains within the range of said window.

13. A method according to claim 12, further comprising the step of subtracting a part of said signal derived from said measured response in order to reduce the effect of a background signal level.

14. A method according to claim 13 and wherein said subtraction step is performed by subtracting said signal derived from said measured response from a reference level.

15. A method according to claim 13 and wherein said subtraction step is performed by differentiating said signal derived from said measured response.

16. A method according to claim 12 wherein said window has a digital range substantially smaller than the range of said digital signal.

17. A method according to claim 12 and wherein said input impulse comprises either one of a single pulse or a train of pulses.

18. A method of measuring an analog signal having a predefined dynamic range, comprising the steps of:
providing an analog to digital converter having a measurement range significantly less than that of said predefined dynamic range;
subtracting an offset from said analog signal to generate an offset signal, said offset being such that said offset signal falls within said measurement range of said analog to digital converter;
using said analog to digital converter to convert said offset signal to a digital offset signal;
repeatedly determining the level of said offset digital signal within said measurement range; and
adjusting said offset if said level of said offset digital signal falls outside of a predetermined portion of said measurement range, such that said offset digital signal remains within said measurement range.

19. A method according to claim 18 and wherein said offset is adjusted if said level of said offset digital signal approaches an extremity of said measurement range by a predetermined amount.

20. A method according to claim 18 and wherein said offset is adjusted if said level of said offset digital signal extends beyond an extremity of said measurement range.

21. A method according to claim 20 and wherein said offset is adjusted if said offset digital signal is either less than the lower extremity of said measurement range, or more than the upper extremity of said measurement range.

22. A method according to claim 18 and which enables said analog to digital converter to handle said analog signal without saturation of said analog to digital converter.
